(19) United States
(12) Patent Application Publication
(10) Pub. No.: US 2007/0274056 A1
(43) Pub. Date: Nov. 29, 2007

(54) Circuit Assembly and Method of its Manufacture

(76) Inventors: Reinhold Schmitt, Aspach (DE); Willibald Konrath, Cottenweiler (DE); Klaus Scholl, Backnang (DE); Haiko Schmelcher, Fichtenberg (DE)

Correspondence Address: Kirchstein Ottinger Israel & Chiffmiller, 489 Fifth Avenue, New York, NY, 10017, US

(21) Appl. No.: 10/561,117

(22) PCT Filed: Jun. 18, 2004
(86) PCT No.: PCT/EP04/51165

§ 371 Date: Mar. 23, 2007

(30) Foreign Application Priority Data
Jun. 18, 2003 (DE) 10327767.6

(51) Int. Cl. H05K 7/14

(52) U.S. Cl. 361/807; 29/842

(57) ABSTRACT

A circuit assembly comprises a circuit board, at least one circuit component connected to the circuit board by wire bonding, and a base plate, on which the circuit board is fixed. A gap between the base plate and the circuit board fixed to it is filled at least locally by a filling body made of a material hardened in the gap.

The present invention relates to a circuit assembly comprising a circuit board, at least one circuit component connected to the circuit board by wire bonding, and a base plate, on which the circuit board is mounted. Such circuit assemblies are used in RF technology, e.g. in microwave transmitters/receivers, where circuit parts that operate at low to medium frequencies are frequently assembled on printed circuit boards, whereas for circuit parts that operate at microwave frequencies, ceramic substrates are preferred.

Signal connections between the low to medium frequency circuit parts and the high frequency circuit parts are made by the wire bonding technique known from IC manufacture. It is found that bonding between the circuit board and the RF frequency circuit components frequently yields bond connections of bad quality, having a high transition impedance and/or little mechanical strength. If a circuit assembly that contains such a bad bond does not operate from the start, this is found out during quality inspection, and the assembly may be discarded, or the fault has to be located and corrected. Both options involve considerable costs for the manufacturer. It may be more problematical if such a bad bond causes a failure only after some delay, when the assembly has already been put into use. In such a case, repair or exchange is considerably more laborious, since typically a service technician must be sent to the user in order to find out the cause of the failure, to remove the relevant assembly, et cetera.

The object of the present invention is, therefore, to provide a circuit assembly having improved reliability, and a method that allows manufacture of such an assembly with a good yield.

The object is achieved by a circuit assembly having the features of claim 1, and a manufacturing method having the features of claim 10, respectively.

The method of manufacture is characterized in that between the conventional step of placing a circuit board and at least one circuit component on a base plate and the step of applying at least one bond wire between the circuit component and a bond pad of the circuit board, a hardenable material is introduced into a gap between them. The gap may result from internal tensions arising when fixing the circuit board to the base plate. By hardening the material in the gap, a positive and integral connection between the circuit board and the base plate is formed.

The method is based on the insight that often the circuit board and the base plate do not touch each other with the required flatness, so that beneath a bond pad, a gap may be present between the circuit board and the base plate which allows the circuit board to yield or to vibrate under the pressure of a bonding tool. This problem is particularly acute in ultrasonic bonding, where the circuit board may be excited to vibrate by the ultrasound applied by the bonding tool. This may hinder the creation of a reliably conductive connection between bond pad and bonding wire.

An insufficient flatness that makes bonding difficult may specifically be caused by the manner in which the circuit board is fixed to the base plate. In particular if the circuit board is screwed to the base plate, it tends to touch the latter only in immediate vicinity of the screws and to warp off the base plate in intermediate regions. By filling the gap at least at selected locations by a hardenable material, which in one embodiment is an electrically conductive adhesive, in accordance with the invention, the circuit board is fixed to the base plate at these locations, so that it neither yields to the pressure of a bonding tool nor vibrates when the filled-in material is hardened.

Preferably, capillary forces between the circuit board and the base plate on the one hand and the hardenable material on the other are made use of for introducing the material into the gap, the material still being in fluid form during the introduction.

The gap may, for example, be filled from an edge the circuit board. Preferably, the material is introduced through a hole in the circuit board, since such a hole may be formed at essentially any location on the circuit board, no matter how far from the edge, where it is desired to support the circuit board by a filling body. The fact that the filling body extends beyond the edges of the hole gives a solid, load-resistant support.

A metallization of the holes is not necessary, so that the circuit board surface necessary to realize them is minimal.

The method may be readily carried out when the hardenable material is an adhesive that is also used in the assembly procedure of the circuit board for cementing circuit components to it. Preferably, the application of the adhesive for cementing these circuit components and the introduction into the gap are carried out in one step during automated assembly of the circuit board.

It is particularly effective if the filling body is located adjacent to a bond pad which is fixed in this way. Preferably, at least two fig bodies are provided at different sides of the bond pad.

Further features and advantages of the invention become apparent by way of example from the subsequent description of an embodiment referring to the appended figures.

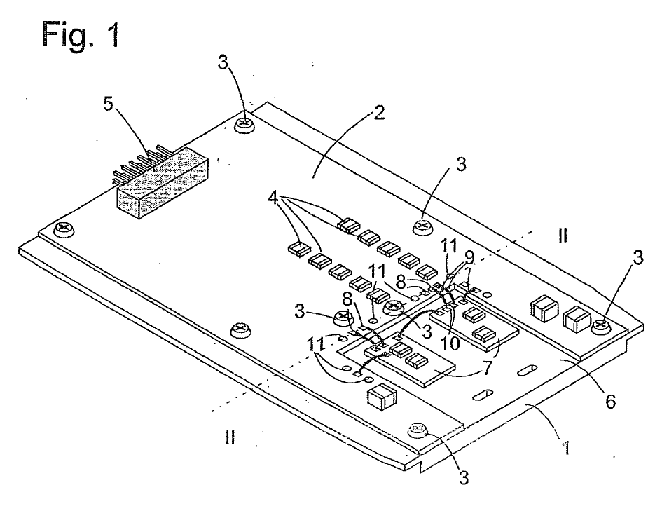

FIG. 1 is a perspective schematic view of a circuit assembly according to the present invention; and

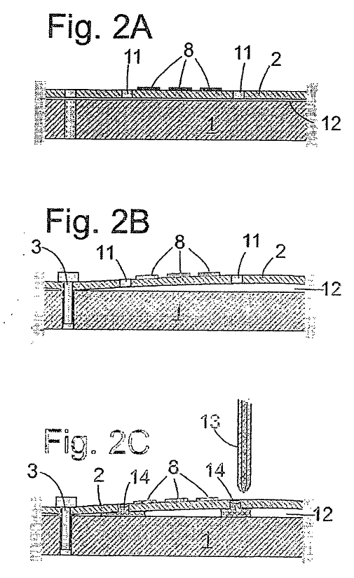

FIGS. 2A to 2D are sections of the circuit assembly of FIG. 1 along line II-II in FIG. 1 in various stages of the manufacture of the assembly.

The assembly shown in perspective in FIG. 1 comprises a base plate 1 of metal on which a printed circuit board 2 is mounted by means of screws 3. Some SMD components 4 and a connector 5 are shown as examples of components mounted on the circuit board 2.

In a cut-out 6 of circuit board 2, two RF circuit components 7 are mounted directly on the base plate 1 by cementing. At the edge of the cut-out 6, adjacent to the RF circuit components 7, several bond pads 8 are formed on the circuit board 2, from which bonding wires 9 extend to corresponding bond pads 10 of the circuit components 7. At two sides, the bond pads 8 of circuit board 2 are surrounded by bores 11 that have no metallization and are not in contact with any of the conductors of circuit board 2. The bores 11 are filled with the same electrically conductive adhesive that is used for cementing the RF circuit components 7 to base plate 1. In order to be able to press the bond pads 8 closely against base plate 1, some of the screws 3 are placed close to the bond pads 8, for example, between two groups of bond pads 8 and/or at a side of a group of bond pads 8 opposite to the cut-out 6.

FIG. 2A shows a first stage of the manufacturing procedure of the circuit assembly of FIG. 1 by means of a partial section along line II-II of FIG. 1. In this stage, the circuit board 2 is laid loosely upon the base plate 1. Since the two facing surfaces of the base plate 1 and the circuit board 2 are never ideally flat, a narrow gap 12 exists between the two. The section also shows two bores 11 and, between these three bond pads 8 at the upper side of circuit board 2.

FIG. 2B shows the same section as FIG. 2A in a stage in which the circuit board 2 is fixed to the ground plate 1 by means of screws 3. The heads of the screws 3 locally exert a high pressure on the circuit board 2 which causes the circuit board 2 to touch the base plate 1 in immediate vicinity of the screws 3, the circuit board 2 locally warping, so that at a larger distance from the screw the gap 12 may even have become wider. If it were intended to bond wires to the bond pads 8 by ultrasound, one would have to press the circuit board 2 flatly against the base plate 1 at the location of the bond pads 8, in order to prevent it from vibrating under the influence of the ultrasound. However, such a pressure cannot be exerted using the bonding tool as this would cause the bonding wires to be crushed at the surface of the pads 8, so that no stress-resistant contact would be created.

FIG. 2C shows the same section after filling the bores 11 with adhesive 14 through the tip 13 of a dispenser. By capillary action, the adhesive advances laterally from the bores 11 into the gap 12 and partially fills it. After hardening, i.e. curing the adhesive 14, the circuit board 2 is positively supported on the base plate 1 by the adhesive. Regions of the circuit board that are not directly supported by the adhesive, such as the central bond pad 8 in FIG. 2C, are at least made sufficiently rigid that they no longer noticeably vibrate.

The bonding wires may be contacted reproducibly and with a good quality, as shown in FIG. 2D.

It is not essential that the same electrically conductive adhesive be used for supporting the circuit board 2 on the base plate 1 that is also used for fixing the components 4 or 5 on the circuit board 2. If a conductive ground layer at the bottom side of circuit board 2 and the base plate 1 are in low impedance contact over a sufficiently large area, it is possible to use a cheap, electrically isolating adhesive. It is also possible to inject solder instead of the adhesive into the bores 11.

1-14. (canceled)

15: A circuit assembly, comprising:
a) a circuit board;
b) at least one circuit component wire bonded to the circuit board;
c) a base plate on which the circuit board is fixed; and
d) a filling body of a material locally filled and hardened in a gap between the base plate and the circuit board.

16: The circuit assembly according to claim 15, in that the filling body is located at a hole in the circuit board.

17: The circuit assembly according to claim 16, in that the filling body engages the hole.

18: The circuit assembly according to claim 16, in that the filling body extends into the gap beyond edges of the hole.

19: The circuit assembly according to claim 16, in that the hole is free from metallization.

20: The circuit assembly according to claim 15, in that the hardened material is an adhesive.

21: The circuit assembly according to claim 20, in that the adhesive is electrically conductive.

22: The circuit assembly according to claim 15, in that the filling body is located adjacent to at least one bond pad.

23: The circuit assembly according to claim 22, in that at least two filling bodies are located at different sides of the at least one bond pad.

24: A method of manufacturing a circuit assembly, comprising the steps of:
a) fixing a circuit board and at least one circuit component on a base plate;
b) applying at least one bonding wire between the at least one circuit component and a bond pad of the circuit board; and
c) introducing a hardenable material into a gap between the circuit board and the base plate after the fixing step, and before the applying step, and allowing the hardenable material to harden in the gap.

25: The method according to claim 24, in that the introducing step is performed using capillary force.

26: The method according to claim 24, in that the introducing step is performed by introducing the hardenable material into the gap through a hole in the circuit board.

27: The method according to claim 24, in that the hardenable material is an adhesive introduced into the gap and applied to at least one of the circuit board and the base plate for cementing the at least one circuit component in a same step.

28: The method according to claim 24, in that the applying step is performed by ultrasonic welding.
